(19) United States
(12) Patent Application Publication
(10) Pub. No.: US 2008/0160710 A1
(43) Pub. Date: Jul. 3, 2008

(54) METHOD OF FABRICATING MOSFET DEVICE

(75) Inventor: Yong Ho OH, Incheon (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/926,026

(22) Filed: Oct. 28, 2007

(30) Foreign Application Priority Data
Dec. 29, 2006 (KR) 10-2006-0137296

(51) Int. Cl. H01L 21/336

(52) U.S. Cl. 438/305; 257/E21.437

(57) ABSTRACT

A method of fabricating a MOSFET device comprising forming a gate electrode pattern on a gate insulating layer on a semiconductor substrate, forming pre-source and pre-drain junction layers using a first ion implantation process on the substrate on each side of the gate electrode pattern, respectively, forming lightly doped drain junctions by performing a second ion implantation process on the surface of the pre-source and pre-drain junction layers, forming spacers on each side of the gate electrode pattern, and forming deep source and deep drain junction layers in the pre-source and pre-drain junction layers by performing third ion implantation process on the area of the substrate next to the gate electrode pattern.

### CROSS-REFERENCE TO RELATED APPLICATIONS

This application claims the benefit of Korean Patent Application No. 10-2006-0137296, filed on Dec. 29, 2006, which is hereby incorporated by reference in its entirety.

### BACKGROUND OF THE INVENTION

1. Field of the Invention

The present invention relates to a method of fabricating a metal-oxide-semiconductor field-effect transistor, or MOSFET device. More specifically, the present invention relates to a method of fabricating a MOSFET device capable of preventing the vertical and lateral diffusion of boron, when boron is used as a dopant of deep source/drain junction in p-channel MOSFIT device.

2. Discussion of the Related Art

Generally, during the fabrication of sub-micron MOSFET semiconductor devices, a dual doped gate structure is formed by injecting gate ions into PMOS and NMOS gate electrodes, respectively. For example, boron ions may be injected into the PMOS gate electrode and P or As ions may be injected into the NMOS gate electrode. Advantageously, this structure is used so as to obtain a surface channel effect that is capable of reducing the short channel effect in the device.

As the size of CMOSFET devices decreases, many efforts have been made to form a shallow junction layer. One difficulty, however, is that in configurations where the PMOS employs a dopant that relatively lighter than the dopant used by the NMOS, an ultrashallow junction is formed. Because of the ultrashallow junction, many efforts have been made to propose a method for preventing the lateral diffusion of the source/drain dopant.

Currently, in order to form a shallow junction layer in a MOSFET semiconductor device, boron ions are injected into the drain and source junction layers on either side of a thin gate oxide layer. Unfortunately, however, the injected boron ions often penetrate and diffuse into the gate oxide layer, resulting in a saturated current and a breakdown in the voltage properties of the semiconductor device.

Moreover, transient enhanced diffusion (TED) may occur when the boron ions are injected into the layers and laterally diffuse toward the channel region by rapid annealing. Thus, the effective channel length is decreased, causing malfunctions in the transistor.

### SUMMARY OF THE INVENTION

Accordingly, the present invention is directed to a method of fabricating a MOSFET device that substantially obviates one or more of the previously mentioned problems, limitations and disadvantages of the related art.

An object of the present invention is to provide a method of fabricating a MOSFET device, by which the vertical and lateral diffusion of the dopant boron can be prevented in a deep source and deep drain junction in PMOS device.

Additional advantages, objects, and features of the invention will be set forth in part in the description which follows and will be apparent to those having ordinary skill in the art and may be learned from practicing of the invention. Furthermore, the objectives and advantages of the invention may be realized using the structure particularly pointed out in the written description and claims hereof as well as the appended drawings.

One aspect of the invention is a method of fabricating a MOSFET device comprising forming a gate insulating layer on a semiconductor substrate, forming a gate electrode pattern on the gate insulating layer so as to form a wall which divides the surface of the substrate into two sides, forming pre-source and pre-drain junction layers by performing first ion implantation on the substrate on each side of the gate electrode pattern, respectively, forming lightly doped drain junction layers by performing a second ion implantation process on the surface of the pre-source and pre-drain junction layers, forming spacers on both sides f the gate electrode pattern wall, and forming deep source and deep drain junction layers in the pre-source and pre-drain junction layers by performing a third ion implantation process on the substrate next to the gate electrode pattern.

It is to be understood that both the foregoing general description and the following detailed description of the present invention are exemplary and explanatory and are intended to provide further explanation of the invention as claimed, without limiting the meaning or scope of the claimed invention.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A to 1D are cross-sectional diagrams illustrating a method of fabricating a MOSFET device according to an embodiment of the present invention.

### DETAILED DESCRIPTION OF THE INVENTION

Reference will now be made in detail to the preferred embodiments of the present invention, using examples which are illustrated in the accompanying drawings. Wherever possible, the same reference numbers will be used throughout the drawings to refer to the same or like parts.

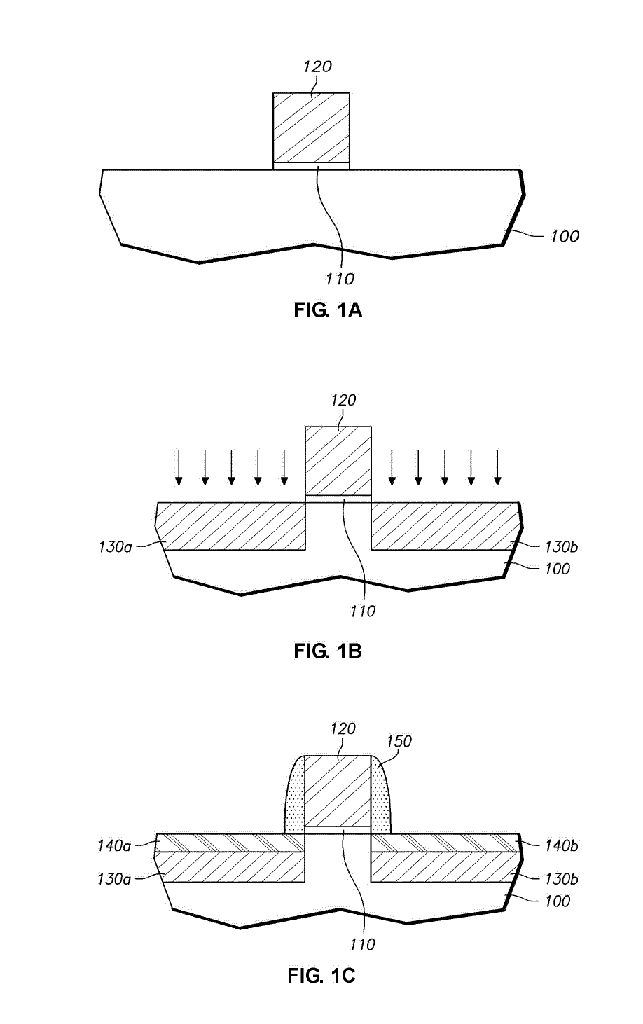

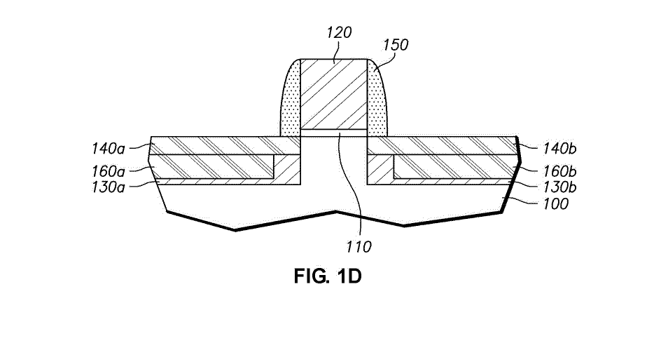

The present invention relates to a method of fabricating a MOSFET device. The method will be described with references to FIGS. 1A-D. The method begins by forming a device isolation layer (not shown in the drawings) can be provided in a field area of a semiconductor substrate 100 in order to define an active area in the semiconductor substrate 100. The device isolation layer may be formed of single crystalline silicon or the like, e.g., using STI (shallow trench isolation). In this example, a conductive single crystalline silicon substrate 100 may be used to form the semiconductor substrate 100, wherein the substrate may have conductive properties corresponding to either n type or a p type. In the embodiment of the present invention, a PMOS device is used as an example with an n-type substrate.

Referring to FIG. 1A, a gate insulating layer 110 is formed on an active area of the substrate 100. More particularly, in this example, an gate insulating layer 110 is formed of SiO₂ by growing the layer 110 in a thermal oxidation process. Next, a gate electrode pattern 120 for a gate electrode is formed on a portion of the gate insulating layer 110. In this example, the conductive layer for a gate electrode is deposited on the substrate 100 including the gate insulating layer 110 by etching the conductive layer for the gate electrode using a photoresist pattern (not shown in the drawing).

Referring now to FIG. 1B, the first ion implantation is carried out on the surface of the substrate 100 on both sides of the gate electrode pattern 120 so as to form a pre-source layers 130a and a pre-drain layer 130b in a well junction structure. In this example, the first ion implantation is preferably carried out with a heavy dose of 10E14˜10E16 ions/cm₂, 20˜50 KeV Ge-ion implantation energy, and 50˜100 KeV F-ion implantation energy. In this case, the Ge-ion implantation energy, the F-ion implantation energy and the dose are each adjustable by modifying the depth and type of deep source/drain junction layers of PMOS that will be formed.

One advantage of using the previously described process which uses the Ge-ion implantation energy and the F-ion implantation energy to form the pre-source and pre-drain junction layers 130a and 130b is that the process helps prevent vertical and lateral diffusions of the boron dopant applied to the deep source and drain junction layers of the PMOS. More specifically, the F (fluorine) ions cover the crystal defect which is generated after the completion of the third ion implantation for the deep source and deep drain junction layers, effectively preventing the transient enhanced diffusion, or TED, of boron ions.

Similarly, the Ge-ion implantation achieves amorphization so as to effectively prevent the vertical diffusion of boron. More particularly, the method forms a self-aligned well using the Ge-ion implantation energy and the F-ion implantation energy capable of suppressing the TED and vertical and lateral diffusions of boron, which cause problems in may MOS devices. Hence, these problems can be effectively suppressed.

Referring to FIG. 1C, second ion implantation is carried out on the upper surfaces of the pre-source and pre-drain junction layers 130a and 130b to so as to form LDD (lightly doped drain) junction layers 140a and 140b.

After the LDD junction layers 140a and 140b have been formed, first spike annealing process is carried out on the LDD junction layers 140a and 140b. Preferably, the first spike annealing is carried out at 1,050˜1,100° C.

Subsequently, spacers 150 are formed on the sides of the gate electrode pattern 120 so as to cover a portion of the LDD junction layers 140a and 140b. In this example the spacers 150 are formed by depositing an insulating layer on the gate electrode pattern 120 and the LDD junction layers 140a and 140b using a deposition process such as a low pressure chemical vapor deposition process, or LPCVD, or the like. Optionally, the insulating layer may have a triple-layered ONO structure including oxide, nitride and oxide. Preferably, the oxide includes TEOS.

The insulating layer is then etched using a dry etch process for anisotropic characteristics, such as an reactive ion etch process and the like. Using the etching process, the insulating layer is etched so as to remain on both of the sidewalls of the gate electrode pattern 120, forming the spacers 150.

Referring now to FIG. 1D, deep source and deep drain junction layers 160a and 160b are formed by performing third ion implantation on the pre-source and pre-drain junction layers 130a and 130b on each side of the gate electrode pattern 120. More particularly, n- or p-type impurity ions, e.g., P-ions (P⁺ and the like) for NMOS can be injected into the substrate 100.

In the present embodiment, for PMOS, boron ions (B+) are heavily injected into the substrate 100 to form the deep source and deep drain junction layers 160a and 160b.

After the deep source and deep drain junction layers 160a and 160b have been formed, a second spike annealing process is carried out on the deep source and deep drain junction layers 160a and 160b so as to help activate of the dopants. Preferably, the second spike annealing process is performed at the same temperature 1,050˜1,100° C. of the first spike annealing.

Hence, the problems with TED and lateral diffusion of boron in PMOS can be effectively solved by forming the self-aligned well type pre-source and pre-drain junction layers using the Ge-ion implantation energy and the F-ion implantation energy before forming the deep source and deep drain junction layers.

Moreover, the previously described process describes the general CMOS process and further includes an ion implantation step which facilitates the formation of the ultrashallow junction, so as to prevent the problem of device performance being degraded by lateral diffusion.

Accordingly, the present invention provides the following effects or advantages.

Firstly, the present invention provides a device which is capable of suppressing TED and lateral diffusion of boron in PMOS before the deep source and deep drain junction layers are formed, by forming self-aligned type pre-source and pre-drain junction layers using Ge-ion implantation energy and F-ion implantation energy. Hence, the aforesaid problems can be effectively solved.

Secondly, the method of the present invention is similar to a general CMOS process, but includes an additional ion implantation step to which facilitates the formation of ultrashallow junction and enhances device performance by suppressing the degradation caused by lateral diffusion.

It will be apparent to those skilled in the art that various modifications and variations can be made in the present invention without departing from the spirit or scope of the inventions. Thus, it is intended that the present invention covers the modifications and variations of this invention within the scope of the appended claims and their equivalents.

What is claimed is:

1. A method of fabricating a MOSFET device, comprising the steps of:
forming a gate insulating layer on a semiconductor substrate;
forming a gate electrode pattern on the gate insulating layer, the gate electrode pattern comprising a wall on the substrate so as to divide the substrate into two sides;
forming a pre-source junction layer and a pre-drain junction layer by performing first ion implantation on the substrate on each side of the gate electrode pattern, respectively;
forming lightly doped drain junction layers on the surface of the pre-source and pre-drain junction layers by performing a second ion implantation process;
forming spacers on the side walls of the gate electrode pattern; and
forming a deep source junction layer and a deep source drain junction layer in the pre-source junction layer and the pre-drain junction layer by performing a third ion implantation process on the area of the substrate next to the gate electrode pattern.

2. The method of claim 1, wherein forming the lightly doped drain junction layers further comprises performing a first spike annealing process on the lightly doped drain junction layers.

3. The method of claim 2, wherein the first spike annealing process is performed at temperature of between 1,050° C. and 1,100° C.

4. The method of claim 1, wherein the first ion implantation process is performed at a dosage of between 10E14 and 10E16 ions/cm₂, Ge-ion implantation energy of between 20 and 50 KeV, and with an F-ion implantation energy of between 50 and 100 KeV.

5. The method of claim 1, wherein forming the deep source junction layer and deep drain junction layer comprises performing a second spike annealing process on the deep source junction layer and the deep drain junction layers.

6. The method of claim 1, wherein the second spike annealing is performed at a temperature between 1,050 and 1,100° C.

7. The method of claim 5, wherein the second spike annealing is performed at a temperature between 1,050 and 1,100° C.

8. A method of fabricating a MOSFET device, comprising the steps of:
forming a gate insulating layer on a semiconductor substrate;
forming a gate electrode pattern on the gate insulating layer, the gate electrode pattern comprising a wall on the substrate so as to divide the substrate into two sides;
forming a pre-source junction layer and a pre-drain junction layer by performing first ion implantation on the substrate on each side of the gate electrode pattern, respectively;
forming lightly doped drain junction layers on the surface of the pre-source and pre-drain junction layers by performing a second ion implantation process and a first spike annealing process on the lightly doped drain junction layers;
forming spacers on the side walls of the gate electrode pattern; and
forming a deep source junction layer and a deep source drain junction layer in the pre-source junction layer and the pre-drain junction layer by performing a third ion implantation process on the area of the substrate next to the gate electrode pattern and a second spike annealing process on the deep source junction layer and the deep drain junction layers.
